(19) United States
(12) Patent Application Publication
(10) Pub. No.: US 2024/0387575 A1
(43) Pub. Date: Nov. 21, 2024

(54) CONVERSION DEVICE, CONVERSION SYSTEM, AND MOVING BODY

(71) Applicant: CANON KABUSHIKI KAISHA, Tokyo (JP)

(72) Inventor: DAIKI SHIRAHIGE, Kanagawa (JP)

(21) Appl. No.: 18/665,314

(22) Filed: May 15, 2024

(30) Foreign Application Priority Data
May 19, 2023 (JP) 2023-083369

(51) Int. Cl. H01L 27/146; G01S 17/89; H04N 25/766

(52) U.S. Cl. CPC H01L 27/14614; G01S 17/89; H04N 25/766

(57) ABSTRACT

A conversion device includes a first component including a first substrate, a conversion unit, a diffusion portion, and a transfer gate. The first substrate includes a first surface and a second surface opposed to the first surface. The conversion unit is arranged in the first substrate. The first component further includes a first embedded electrode connected to the conversion unit, and a second embedded electrode connected to the diffusion portion. A depth from the first surface to an end portion of the first embedded electrode on a second surface side and a depth from the first surface to an end portion of the second embedded electrode on the second surface side are different from each other.

### BACKGROUND

### Technical Field

The aspect of the embodiments relates to a conversion device, a conversion system and a moving body.

### Description of the Related Art

International Publication No. WO 2022/138914 discusses that a photoelectric conversion unit is arranged on a first semiconductor layer, a pixel circuit is arranged on a second semiconductor layer, and a contact electrode is embedded to achieve miniaturization of pixels.

However, in International Publication No. WO 2022/138914, suppression of noise that may be generated in the embedded contact electrode is not considered.

### SUMMARY

According to an aspect of the embodiments, a conversion device includes a first component including a first substrate, a conversion unit, a diffusion portion, and a transfer gate, the first substrate including a first surface and a second surface opposed to the first surface, the conversion unit being arranged in the first substrate, the transfer gate being arranged on a first surface side of the first substrate and being configured to transfer a signal charge generated in the conversion unit to the diffusion portion, wherein the first component further includes a first embedded electrode connected to the conversion unit, and a second embedded electrode connected to the diffusion portion, and wherein a depth from the first surface to an end portion of the first embedded electrode on a second surface side and a depth from the first surface to an end portion of the second embedded electrode on the second surface side are different from each other.

Further features of the disclosure will become apparent from the following description of exemplary embodiments with reference to the attached drawings.

### BRIEF DESCRIPTION OF THE DRAWINGS

FIG. 1 is a block diagram schematically illustrating a configuration of a photoelectric conversion device according to a first exemplary embodiment.

FIG. 2 is an equivalent circuit diagram of pixels of the photoelectric conversion device according to the first exemplary embodiment.

FIG. 3 is a plan view of the pixels of the photoelectric conversion device according to the first exemplary embodiment.

FIG. 4 is a cross-sectional view of the pixels of the photoelectric conversion device according to the first exemplary embodiment.

FIG. 5 is a cross-sectional view of pixels of a photoelectric conversion device according to a second exemplary embodiment.

FIG. 6 is a cross-sectional view of pixels of a photoelectric conversion device according to a third exemplary embodiment.

FIG. 7 is a cross-sectional view of pixels of a photoelectric conversion device according to a fourth exemplary embodiment.

FIG. 8 is a cross-sectional view of pixels of a photoelectric conversion device according to a fifth exemplary embodiment.

FIG. 9 is a cross-sectional view of pixels of a photoelectric conversion device according to a sixth exemplary embodiment.

FIG. 10 is a plan view of pixels of a photoelectric conversion device according to a seventh exemplary embodiment.

FIG. 11 is a cross-sectional view of the pixels of the photoelectric conversion device according to the seventh exemplary embodiment.

FIG. 12 is a functional block diagram of a photoelectric conversion system according to an eighth exemplary embodiment.

FIGS. 13A and 13B are functional block diagrams of a photoelectric conversion system according to a ninth exemplary embodiment.

FIG. 14 is a functional block diagram of a photoelectric conversion system according to a tenth exemplary embodiment.

FIG. 15 is a functional block diagram of a photoelectric conversion system according to an eleventh exemplary embodiment.

FIGS. 16A and 16B are functional block diagrams of a photoelectric conversion system according to a twelfth exemplary embodiment.

### DESCRIPTION OF THE EMBODIMENTS

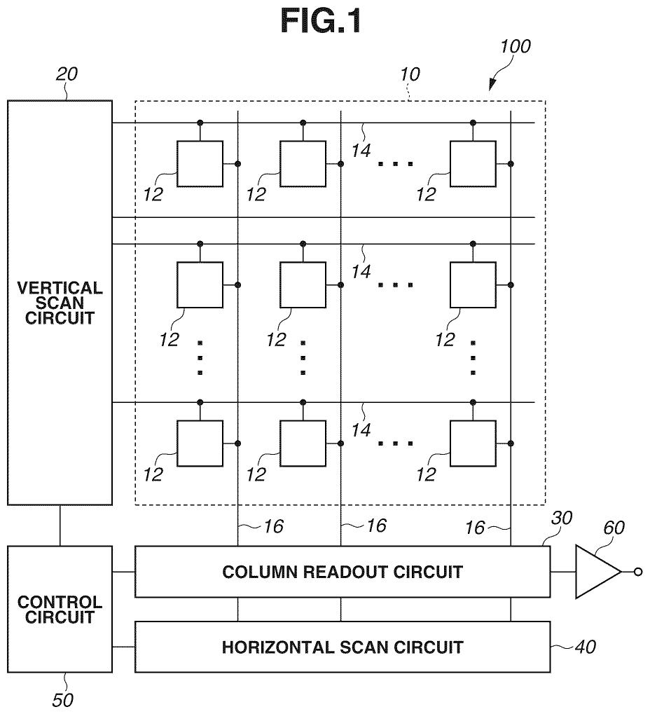

A photoelectric conversion device according to a first exemplary embodiment of the present disclosure is described with reference to FIG. 1 to FIG. 4.

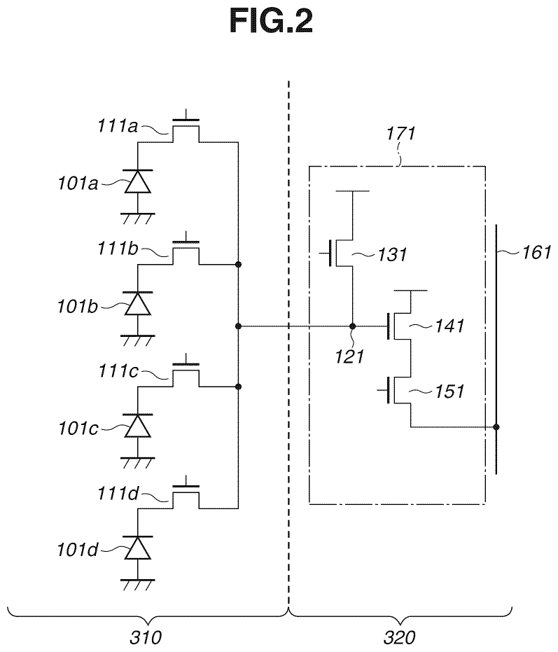

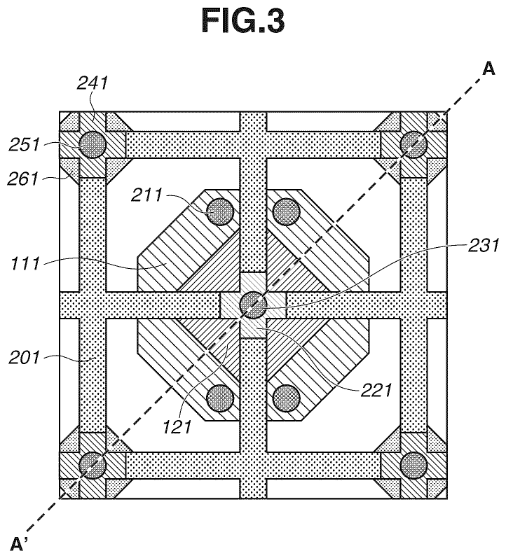

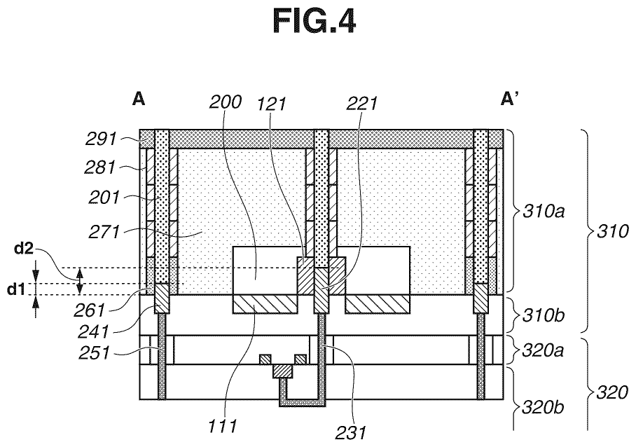

FIG. 1 is a block diagram schematically illustrating a configuration of the photoelectric conversion device according to the present exemplary embodiment. FIG. 2 is an equivalent circuit diagram of pixels of the photoelectric conversion device according to the present exemplary embodiment. FIG. 3 illustrates a planar layout of the pixels of the photoelectric conversion device according to the present exemplary embodiment. FIG. 4 is a diagram illustrating a cross-section of the pixels of the photoelectric conversion device according to the present exemplary embodiment.

As illustrated in FIG. 1, a photoelectric conversion device 100 according to the present exemplary embodiment includes a pixel region 10, a vertical scan circuit 20, a column readout circuit 30, a horizontal scan circuit 40, a control circuit 50, and an output circuit 60.

In the pixel region 10, a plurality of pixels 12 arranged in a matrix extending over a plurality of rows and a plurality of columns is disposed. Control signal lines 14 extending in a row direction (lateral direction in FIG. 1) are arranged for respective rows of a pixel array of the pixel region 10. Each of the control signal lines 14 is connected to the pixels 12 arranged in the row direction, and serves as a signal line common to the pixels 12. Further, vertical output lines 16 extending in a column direction (vertical direction in FIG. 1) are arranged for respective columns of the pixel array of the pixel region 10. Each of the vertical output lines 16 is connected to the pixels 12 arranged in the column direction, and serves as a signal line common to the pixels 12.

The control signal lines 14 of the respective rows are connected to the vertical scan circuit 20. The vertical scan circuit 20 is a circuit unit that supplies, when pixel signals are read from the pixels 12, control signals for driving readout circuits in the pixels 12, to the pixels 12 through the control signal lines 14. One ends of the vertical output lines 16 in the respective columns are connected to the column readout circuit 30. The pixel signals read out from the pixels 12 are input to the column readout circuit 30 through the vertical output lines 16. The column readout circuit 30 is a circuit unit that performs predetermined signal processing, such as amplification processing and analog-to-digital (AD) conversion processing, on the pixel signals read out from the pixels 12. The column readout circuit 30 may include a differential amplifier circuit, a sample-and-hold circuit, and an AD conversion circuit.

The horizontal scan circuit 40 is a circuit unit that supplies, to the column readout circuit 30, control signals for sequentially transferring the pixel signals processed by the column readout circuit 30 to the output circuit 60 on a column basis. The control circuit 50 is a circuit unit that supplies control signals for controlling operation and timings of the operation of the vertical scan circuit 20, the column readout circuit 30, and the horizontal scan circuit 40. The output circuit 60 is a circuit unit that includes a buffer amplifier and a differential amplifier, and outputs the pixel signals read from the column readout circuit 30 to a signal processing unit outside the photoelectric conversion device 100.

FIG. 2 is an equivalent circuit diagram of four pixels. FIG. 2 illustrates an example in which floating diffusions (FDs) 121 of a plurality of photodiodes (PDs) 101, which are photoelectric conversion units, are electrically connected to one another, and are electrically connected to an input terminal of a common pixel circuit 171. In FIG. 2, to distinguish between the photoelectric conversion units 101 and the like corresponding to the respective pixels, suffixes a to d are added to respective reference numerals. As described above, one pixel circuit 171 is arranged to the plurality of photoelectric conversion units 101, which makes it possible to reduce an area occupied by the pixel circuit 171 in the entire photoelectric conversion device. In this example, the circuit configuration in which one FD 121 is shared by the four pixels is illustrated; however, the number of pixels sharing the FD 121 is not limited to four, and it is sufficient for the FD 121 to be electrically connected to at least two pixels.

Each of the photoelectric conversion units 101 generates charges in response to incidence of light. A transfer transistor 111 is a transistor that transfers the charges generated in the corresponding photoelectric conversion unit 101.

A cathode of each of the photoelectric conversion units 101 is electrically connected to a source of the corresponding transfer transistor 111, and an anode of each of the photoelectric conversion units 101 is electrically connected to a reference potential line (e.g., ground). A drain of each transfer transistor 111 is electrically connected to the FD 121, and a gate of the transfer transistor 111 is electrically connected to a pixel drive line (not illustrated).

The charges output from each of the photoelectric conversion units 101 through the corresponding transfer transistor 111 are temporarily stored in the FD 121.

The pixel circuit 171 includes, for example, a reset transistor 131, a selection transistor 151, and an amplification transistor 141.

A gate of the reset transistor 131 is electrically connected to the pixel drive line (not illustrated). A source of the amplification transistor 141 is electrically connected to a drain of the selection transistor 151, and a gate of the amplification transistor 141 is electrically connected to a source of the reset transistor 131. A source of the selection transistor 151 (output terminal of the pixel circuit 171) is electrically connected to an output line 161, and a gate of the selection transistor 151 is electrically connected to the pixel drive line (not illustrated).

When the transfer transistor 111 is turned on, the transfer transistor 111 transfers the charges of the corresponding PD 101 to the FD 121. The gate (transfer gates) of the transfer transistor 111 is disposed on a surface of a semiconductor layer. Alternatively, the gate of the transfer transistor 111 may extend from the surface of the semiconductor layer to a depth reaching the photoelectric conversion unit 101. In other words, the gate of the transfer transistor 111 may be a vertical transfer gate.

The reset transistor 131 resets a potential of the FD 121 to a predetermined potential. When the reset transistor 131 is turned on, the reset transistor 131 resets the potential of the FD 121 to a potential of a power supply line VDD.

The selection transistor 151 controls an output timing of a pixel signal from the pixel circuit 171. The selection transistor 151 may be omitted as necessary. The source of the reset transistor 131 (input terminal of pixel circuit 171) is electrically connected to the FD 121, and a drain of the reset transistor 131 is electrically connected to the power supply line VDD and a drain of the amplification transistor 141.

The amplification transistor 141 generates a signal of a voltage corresponding to a level of the charges held by the FD 121, as the pixel signal. The amplification transistor 141 constitutes a source-follower amplifier, and outputs the pixel signal of the voltage corresponding to the level of the charges generated in the photoelectric conversion units 101. When the selection transistor 151 is turned on, the amplification transistor 141 amplifies the potential of the FD 121, and outputs a voltage corresponding to the potential to a column circuit (not illustrated) through the output line 161.

Alternatively, the selection transistor 151 may be arranged between the power supply line VDD and the amplification transistor 141. In this case, the drain of the reset transistor 131 is electrically connected to the power supply line VDD and the drain of the selection transistor 151. The source of the selection transistor 151 is electrically connected to the drain of the amplification transistor 141, and the gate of the selection transistor 151 is electrically connected to the pixel drive line (not illustrated). The source of the amplification transistor 141 is electrically connected to the output line 161, and the gate of the amplification transistor 141 is electrically connected to the source of the reset transistor 131.

A dotted line in FIG. 2 indicates a boundary between a first component 310 and a second component 320. The PDs 101 and the transfer transistors 111 are disposed on the first component 310, and the reset transistor 131, the amplification transistor 141 and the selection transistor 151 are disposed on the second component 320.

FIG. 3 is a plan view of the first component 310 of the photoelectric conversion device according to the present exemplary embodiment. FIG. 3 illustrates a planar structure corresponding to four PDs 101 sharing one FD 121.

The four PDs 101 are arranged in two rows and two columns, and the PDs 101 are separated from one another by a lattice-shaped separation portion 201. The FD 121 shared by the four PDs 101 is arranged at a position adjacent to all of the four PDs 101. In the photoelectric conversion device according to the present exemplary embodiment, the FD 121 is arranged at a center of the four PDs 101 arranged in two rows and two columns. The FD 121 includes a first embedded electrode 221, and a first through electrode 231 is connected to the first embedded electrode 221. Gates of the transfer transistors 111 that transfer the charges photoelectrically converted by the PDs 101 to the FD 121 are disposed in proximity of the FD 121. Through electrodes 211 that supply a voltage for controlling driving of the transfer transistors 111 are connected to the respective gates of the transfer transistors 111.

In each of the four PDs 101, a second through electrode 251 is electrically connected to a semiconductor region 261 via a second embedded electrode 241.

The through electrodes 211 connected to the respective gates of the transfer transistors 111, the first through electrode 231, and second through electrodes 251 each extend toward the second component 320.

FIG. 4 is a cross-sectional view taken along line A-A′in FIG. 3. The photoelectric conversion device according to the present exemplary embodiment has a structure in which the first component 310 and the second component 320 are stacked. The first component 310 includes a first substrate 310a and a first wiring layer 310b, and the second component 320 includes a second substrate 320a and a second wiring layer 320b. FIG. 4 illustrates the first component 310, the second substrate 320a, and a part of the second wiring layer 320b.

The PDs 101 and the transfer transistors 111 are disposed on the first substrate 310a. The separation portion 201 separates the PDs 101 from one another, and the first embedded electrode 221 and the second embedded electrode 241 are disposed at a boundary among the PDs 101. An N-type semiconductor region 121 (the FD 121) is arranged around the first embedded electrode 221, and a P-type semiconductor region 261 is arranged around the second embedded electrode 241. A P-type semiconductor region 281 is arranged along the separation portion 201, and a P-type semiconductor region 291 is disposed on a light incident surface side of the first substrate 310a. The voltage is supplied from the second through electrode 251 to the semiconductor regions 281 and 291 through the semiconductor region 261. The semiconductor regions 281 and 291 each form a PN junction with an N-type semiconductor region 271 and function as the PD 101. The gate of the transfer transistor 111 is arranged between the FD 121 and the semiconductor region 271, and transfers the charges converted by the PD 101 to the FD 121. A semiconductor region 200 is arranged around the transfer transistor 111.

The pixel circuit 171 is arranged on the second substrate 320a. Further, through holes are arranged in the second substrate 320a, and the first through electrode 231 and the second through electrodes 251 are disposed to pass through the through holes. Each of the through electrodes is made of, for example, tungsten, and an insulation film is arranged between each of the through electrodes and the second substrate 320a. As described above, the first through electrode 231 and the second through electrode 251 are connected to the first embedded electrode 221 and the second embedded electrode 241, respectively. Each of the embedded electrodes is made of, for example, polycrystalline silicon doped with an impurity.

In a case where the first embedded electrode 221 is not used, and an electrode is arranged on a surface of the first substrate 310a, in one embodiment, the first through electrode 231 is connected to the first substrate 310a of the pixels 12 and to supply a voltage. More specifically, the first through electrode 231 is connected to the semiconductor region 121. In this case, the semiconductor region 121 having a relatively large area is disposed in order to reduce occurrence of a failure caused by positional deviation of the first through electrode 231 and the like in a manufacturing process. Accordingly, to maintain a pixel pitch, a region allocated to the PD 101 and the like in each of the pixels is reduced. As with the photoelectric conversion device according to the present exemplary embodiment, providing the first embedded electrode 221 makes it possible to form a contact with a smaller area and with little contact resistance. This makes it possible to achieve an effect beneficial for miniaturization.

Each of the first embedded electrode 221 and the second embedded electrode 241 is configured in a shape embedded in a groove formed in the first substrate 310a. As a result, each of the first embedded electrode 221 and the second embedded electrode 241 is connected to the first substrate 310a adjacent to the groove on a side surface of each of the embedded electrodes. A connection surface between the first substrate 310a and each of the first embedded electrode 221 and the second embedded electrode 241 is arranged in a direction perpendicular to a surface of the first substrate 310a, which makes it possible to reduce connection resistance. Accordingly, it is possible to reduce areas occupied by the first embedded electrode 221 and the second embedded electrode 241, and to enlarge an area occupied by the PD 101.

An embedded depth (“d2” in FIG. 4) of the first embedded electrode 221 and the like to the first substrate 310a is, in one embodiment, 50 nm or more. This is because the connection surface between the first substrate 310a and each of the first embedded electrode 221 and the second embedded electrode 241 can be enlarged, and the connection resistance can be reduced.

On the other hand, in a case where the first embedded electrode 221 and the second embedded electrode 241 are formed at deep positions in the first substrate 310a, there is concern that a dark current generated around the contact may be increased.

In the photoelectric conversion device according to the present exemplary embodiment, the depth (d2) from a surface (first surface) of the first substrate 310a opposed to the light incident surface to an end portion of the first embedded electrode 221 on the light incident surface (second surface) side is greater than a depth (d1) from the first surface to an end portion of the second embedded electrode 241 on the second surface side. Such a configuration makes it possible to suppress the dark current generated around the second embedded electrode 241 while suppressing the contact resistance of the first embedded electrode 221. In FIG. 3 and FIG. 4, the first embedded electrode 221 and the second embedded electrode 241 are illustrated to have an equivalent size in a planar view; however, the size is not limited thereto, and the first embedded electrode 221 and the second embedded electrode 241 may have sizes different from each other. In addition, it is not necessary that the configuration be satisfied in all of the pixels in the pixel array of the pixel region 10, and the depth of the first embedded electrode 221 and the depth of the second embedded electrode 241 may be different in some of the pixels.

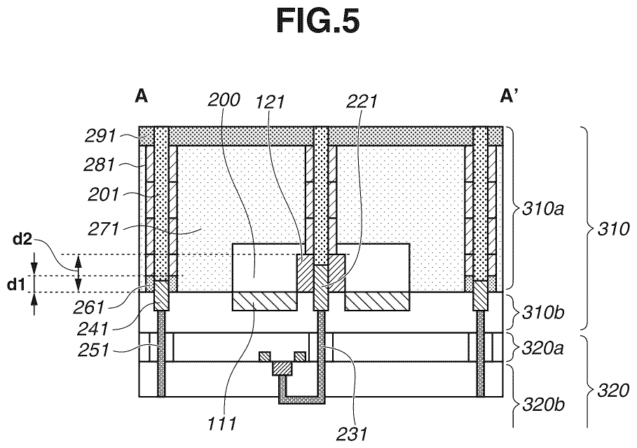

A photoelectric conversion device according to a second exemplary embodiment is described with reference to FIG. 5. The second exemplary embodiment is a modification of the first exemplary embodiment. Description common to the first exemplary embodiment is omitted, and differences from the first exemplary embodiment are mainly described.

When the second embedded electrode 241 is formed at the deep position in the substrate, in a case where the P-type semiconductor region 261 around the second embedded electrode 241 is also formed at the deep position, there is concern that the volume of the PD 101 and an accumulable saturation charge amount are reduced. In the photoelectric conversion device according to the present exemplary embodiment, the P-type semiconductor region 261 around the second embedded electrode 241 is formed at a shallow position as compared with the N-type semiconductor region 121 around the first embedded electrode 221. In other words, in a comparison with regard to the depth from the surface (first surface) opposed to the light incident surface, the end portion of the N-type semiconductor region 121 on the light incident surface (second surface) side is close to the second surface compared with the end portion of the P-type semiconductor region 261 on the second surface side. Therefore, an effect of preventing reduction of the charge amount accumulated around the first embedded electrode 221 can be obtained. Further, the P-type semiconductor region 261 around the second embedded electrode 241 may be formed smaller than the N-type semiconductor region 121 around the first embedded electrode 221 in a planar view. This makes it possible to further prevent the reduction of the charge amount accumulated around the first embedded electrode 221.

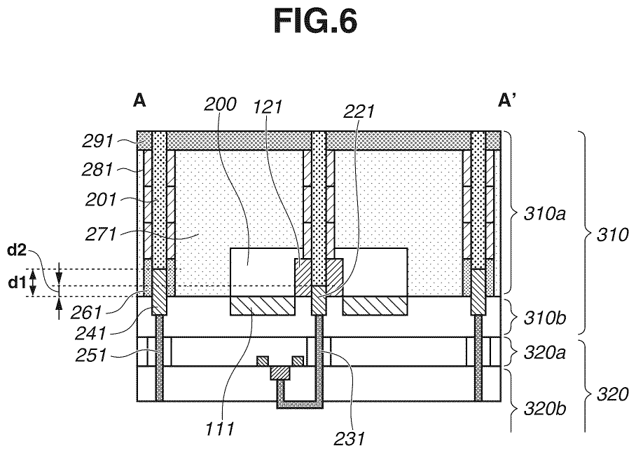

A photoelectric conversion device according to a third exemplary embodiment is described with reference to FIG. 6. The photoelectric conversion device according to the third exemplary embodiment is described. Description common to the first exemplary embodiment is omitted, and differences from the first exemplary embodiment are mainly described.

In the photoelectric conversion device according to the present exemplary embodiment, in contrast to the photoelectric conversion device according to the first exemplary embodiment, the depth (d1) from the surface (first surface) of the first substrate 310a opposed to the light incident surface to the end portion of the second embedded electrode 241 on the light incident surface (second surface) side is greater than the depth (d2) from the first surface to the end portion of the first embedded electrode 221 on the second surface side. Such a configuration makes it possible to suppress the dark current generated around the first embedded electrode 221 while suppressing contact resistance of the second embedded electrode 241.

As in the first exemplary embodiment, the first embedded electrode 221 and the second embedded electrode 241 may be made different in size in a planar view from each other, and the depth of the first embedded electrode 221 and the depth of the second embedded electrode 241 may be different only in some of the pixels.

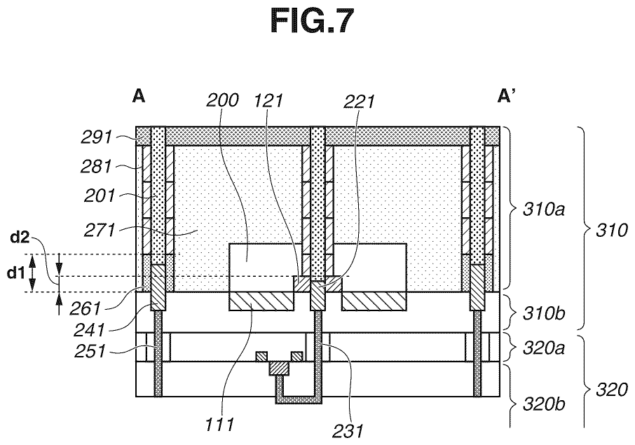

A photoelectric conversion device according to a fourth exemplary embodiment is described with reference to FIG. 7. The fourth exemplary embodiment is a modification of the third exemplary embodiment. Description common to the third exemplary embodiment is omitted, and differences from the third exemplary embodiment are mainly described.

In a case where the N-type semiconductor region 121 around the first embedded electrode 221 is formed at a deep position in the substrate, a gain at a charge-voltage conversion is reduced because an FD capacitance is increased. Therefore, a rate of a circuit noise component to the signals output from the pixels is increased, and a signal-to-noise (SN) ratio may be deteriorated.

In the present exemplary embodiment, the N-type semiconductor region 121 around the first embedded electrode 221 is formed at a shallow position as compared with the P-type semiconductor region 261 around the second embedded electrode 241. In other words, in a comparison with regard to the depth from the surface (first surface) opposed to the light incident surface, the end portion of the N-type semiconductor region 121 on the light incident surface (second surface) side is close to the first surface compared with the end portion of the P-type semiconductor region 261 on the second surface side. By such a configuration, the FD capacitance is reduced to achieve a noise suppression effect while recombination of the dark current generated in the first embedded electrode 221 is facilitated.

As in the second exemplary embodiment, the N-type semiconductor region 121 around the first embedded electrode 221 and the P-type semiconductor region 261 around the second embedded electrode 241 may be made different in size in a planar view from each other. This makes it possible to obtain the noise suppression effect more strongly.

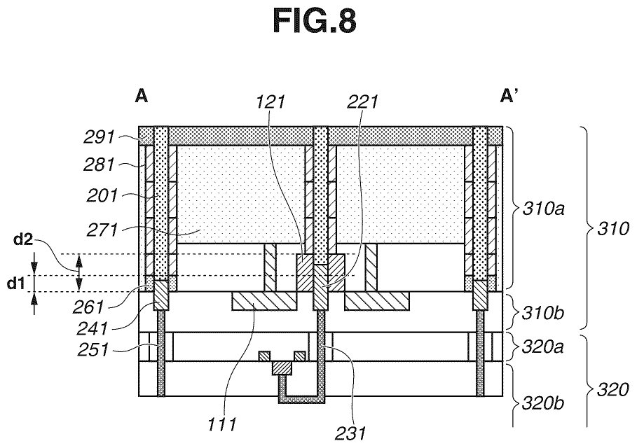

A photoelectric conversion device according to a fifth exemplary embodiment is described with reference to FIG. 8. The fifth exemplary embodiment is a modification of the first exemplary embodiment. Description common to the first exemplary embodiment is omitted, and differences from the first exemplary embodiment are mainly described. The gate of the transfer transistor 111 of the photoelectric conversion device according to the present exemplary embodiment is a vertical transfer gate.

In a case where the vertical transfer gate is used as the gate of the transfer transistor 111, when the charges photoelectrically converted by the PDs 101 are transferred to the FD 121, movement of the charges in the vertical direction toward the surface (first surface) of the first substrate 310a occurs. At this time, part of the charges may not be transferred to the FD 121 within a transfer period, and an image lag may occur.

The photoelectric conversion device according to the present exemplary embodiment has a structure in which the N-type semiconductor region 121 around the first embedded electrode 221 is formed at a deep position in the first substrate 310a. As a result, a moving amount of the charges in the vertical direction when the charges move from the PDs 101 to the FD 121 is reduced, and the charges can be transferred to the FD 121 in a shorter transfer period. Accordingly, it is possible to realize the photoelectric conversion device with the image lag being suppressed.

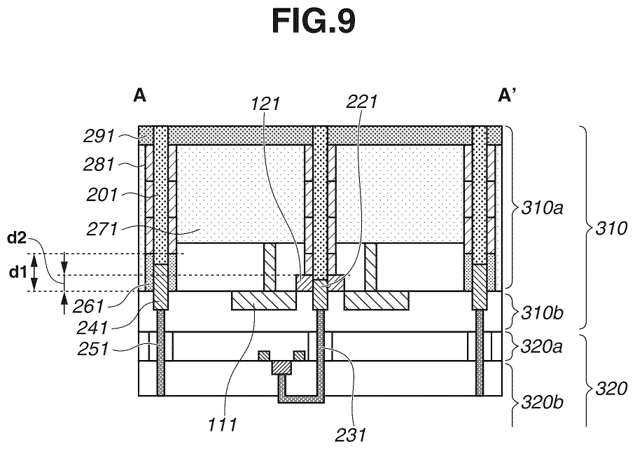

A photoelectric conversion device according to a sixth exemplary embodiment is described with reference to FIG. 9. The sixth exemplary embodiment is a modification of the third exemplary embodiment. Description common to the third exemplary embodiment is omitted, and differences from the third exemplary embodiment are mainly described. The gate of the transfer transistor 111 of the photoelectric conversion device according to the present exemplary embodiment is a vertical transfer gate.

In the case where the vertical transfer gate is used as the gate of the transfer transistor 111, when the FD 121 is formed at a deep position in the first substrate 310a, a distance between the FD 121 and each of the PDs 101 similarly formed at the deep position in the first substrate 310a is reduced. When the distance between each of the PDs 101 and the FD 121 is reduced, a potential barrier to signal charges between each of the PDs 101 and the FD 121 is lowered, and the charges accumulated in the PDs 101 easily leak to the FD 121. Further, when the PDs 101 are saturated, a part of the charges accumulated in the PDs 101 overflow to the FD 121. At this time, an overflow amount is increased as the potential barrier between each of the PDs 101 and the FD 121 is lower. Thus, a saturation charge amount of the FD 121 may be lowered.

In the photoelectric conversion device according to the present exemplary embodiment, the first embedded electrode 221 is formed at a shallow position as compared with the second embedded electrodes 241. This makes it possible to secure the distance between each of the PDs 101 and the FD 121 while reducing the contact resistance of the second embedded electrode 241. As a result, it is possible to increase the saturation charge amount of the FD 121.

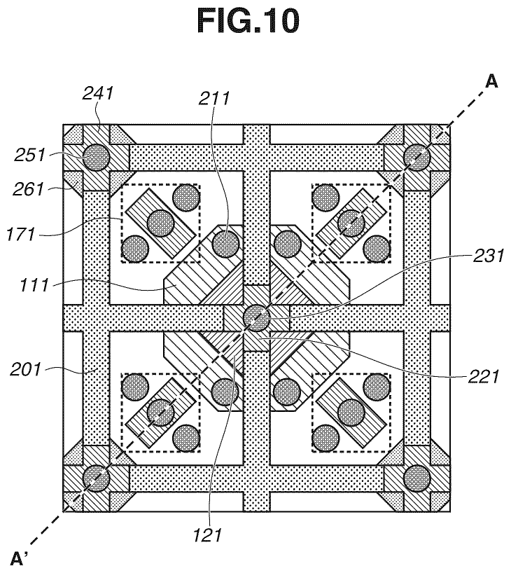

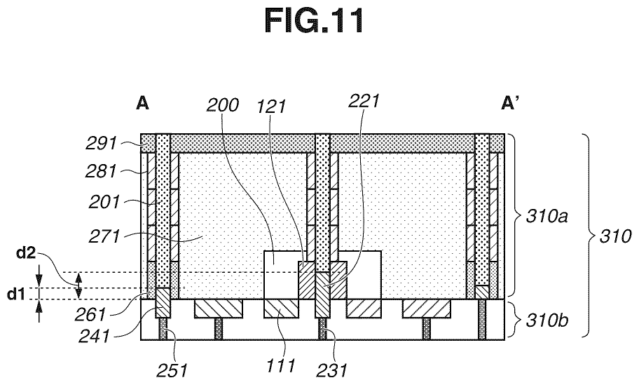

A photoelectric conversion device according to a seventh exemplary embodiment is described with reference to FIG. 10 and FIG. 11. Description common to the first exemplary embodiment is omitted, and differences from the first exemplary embodiment are mainly described. The photoelectric conversion device according to the present exemplary embodiment is different from the photoelectric conversion device according to the first exemplary embodiment in that the pixel circuit 171 is arranged in the first substrate 310a.

FIG. 10 is a plan view of the first substrate 310a, and FIG. 11 is a cross-sectional view taken along line A-A′ in FIG. 10. The gates of the transistors (e.g., amplification transistor 141 and selection transistor 151) constituting the pixel circuit 171, and electrodes connected to the transistors are arranged.

As in the first exemplary embodiment, the first embedded electrode 221 of the photoelectric conversion device according to the present exemplary embodiment is arranged at a deep position in the first substrate 310a as compared with the second embedded electrode 241. The configuration brings about an effect of suppressing a dark current generated in the second embedded electrode 241. A configuration similar to the configuration according to the fourth exemplary embodiment may be applied to a photoelectric conversion device in which the pixel circuit 171 is also arranged on the same substrate as the PDs 101. In other words, the second embedded electrode 241 may be arranged at a deep position in the first substrate 310a as compared with the first embedded electrode 221. With such a configuration, a noise suppression effect can be expected.

As described above, even the photoelectric conversion device in which the pixel circuit 171 is also arranged on the same substrate as the PDs 101 can bring about effects of the aspect of the embodiments by making the depth of the first embedded electrode 221 and the depth of the second embedded electrodes 241 different from each other.

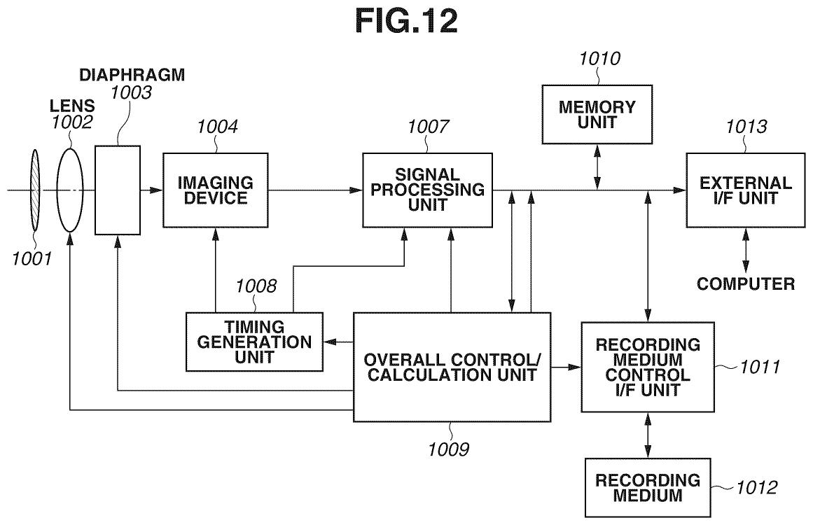

A photoelectric conversion system according to an eighth exemplary embodiment is described with reference to FIG. 12. FIG. 12 is a block diagram schematically illustrating a configuration of the photoelectric conversion system according to the present exemplary embodiment.

The photoelectric conversion devices according to the above-described first to seventh exemplary embodiments are each applicable to various photoelectric conversion systems. Examples of the applicable photoelectric conversion system include a digital still camera, a digital camcorder, a monitoring camera, a copier, a facsimile, a mobile phone, an on-vehicle camera, and an observation satellite. Further, a camera module including an optical system such as a lens, and an imaging device is also included in the photoelectric conversion system. FIG. 12 is a block diagram of a digital still camera as an example.

The photoelectric conversion system illustrated in FIG. 12 includes an imaging device 1004 that is an example of the photoelectric conversion device, and a lens 1002 forming an optical image of an object on the imaging device 1004. The photoelectric conversion system further includes a diaphragm 1003 for varying a quantity of light passing through the lens 1002, and a barrier 1001 for protecting the lens 1002. The lens 1002 and the diaphragm 1003 are included in an optical system that condenses light to the imaging device 1004. The imaging device 1004 is the photoelectric conversion device according to any of the above-described exemplary embodiments, and converts the optical image formed by the lens 1002 into an electric signal.

The photoelectric conversion system further includes a signal processing unit 1007 that is an image generation unit that generates an image by processing an output signal output from the imaging device 1004. The signal processing unit 1007 performs various kinds of correction and compression as necessary and an operation to output image data. The signal processing unit 1007 may be formed on a semiconductor substrate on which the imaging device 1004 is arranged, or may be formed on a semiconductor substrate different from the semiconductor substrate on which the imaging device 1004 is arranged.

The photoelectric conversion system further includes a memory unit 1010 that temporarily stores the image data, and an external interface unit (external I/F unit) 1013 for communication with an external computer and the like. The photoelectric conversion system further includes a recording medium 1012, such as a semiconductor memory, for recording and reading of imaging data, and a recording medium control interface unit (recording medium control I/F unit) 1011 for performing the recording and reading of the imaging data to and from the recording medium 1012. The recording medium 1012 may be incorporated in the photoelectric conversion system, or may be detachable.

The photoelectric conversion system further includes an overall control/calculation unit 1009 that performs various kinds of calculation and controls the whole of the digital still camera, and a timing generation unit 1008 that outputs various kinds of timing signals to the imaging device 1004 and the signal processing unit 1007. The timing signals and the like may be input from outside, and it is sufficient for the photoelectric conversion system to include at least the imaging device 1004 and the signal processing unit 1007 that processes the output signal output from the imaging device 1004.

The imaging device 1004 outputs an imaging signal to the signal processing unit 1007. The signal processing unit 1007 performs predetermined signal processing on the imaging signal output from the imaging device 1004, and outputs image data. The signal processing unit 1007 generates an image by using the imaging signal.

As described above, according to the present exemplary embodiment, it is possible to realize the photoelectric conversion system to which the photoelectric conversion device (imaging device) according to any of the above-described exemplary embodiments is applied.

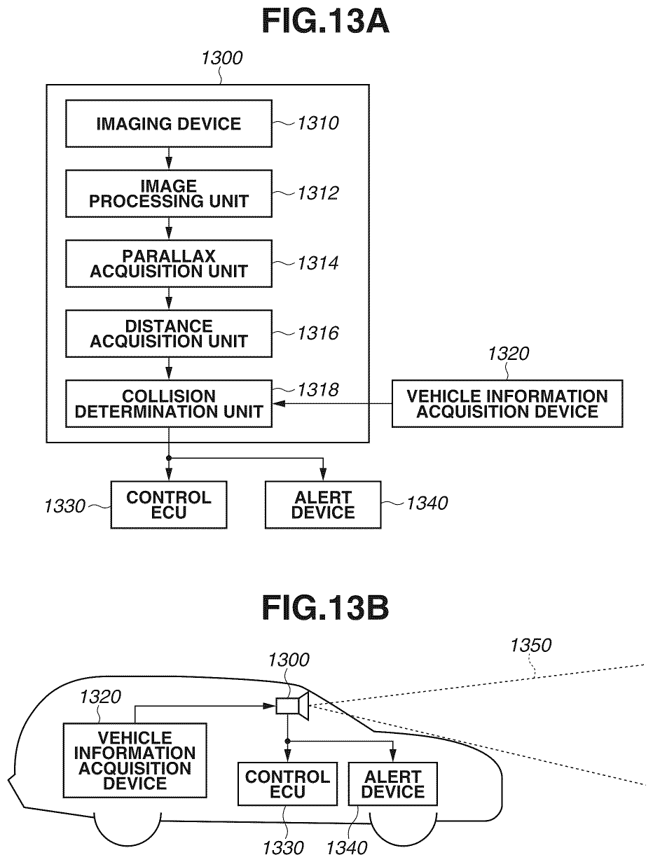

A photoelectric conversion system and a moving body according to a ninth exemplary embodiment are described with reference to FIGS. 13A and 13B. FIGS. 13A and 13B are diagrams illustrating configurations of the photoelectric conversion system and the moving body according to the present exemplary embodiment.

FIG. 13A illustrates an example of the photoelectric conversion system relating to an on-vehicle camera. A photoelectric conversion system 1300 includes an imaging device 1310. The imaging device 1310 is the photoelectric conversion device according to any of the above-described exemplary embodiments. The photoelectric conversion system 1300 includes an image processing unit 1312 that performs image processing on a plurality of pieces of image data acquired by the imaging device 1310, and a parallax acquisition unit 1314 that calculates parallax (phase difference of parallax images) from the plurality of pieces of image data acquired by the photoelectric conversion system 1300. The photoelectric conversion system 1300 further includes a distance acquisition unit 1316 that calculates a distance to an object based on the calculated parallax, and a collision determination unit 1318 that determines whether there is a possibility of collision based on the calculated distance. The parallax acquisition unit 1314 and the distance acquisition unit 1316 are each an example of a distance information acquisition unit that acquires information on the distance to the object. In other words, the information on the distance includes pieces of information about the parallax, a defocus amount, the distance to the object, and the like. The collision determination unit 1318 may determine the possibility of collision by using any piece of the information on the distance. The distance information acquisition unit may be implemented by exclusively designed hardware or a software module.

Further, the distance information acquisition unit may be implemented by a field programmable gate array (FPGA), an application specific integrated circuit (ASIC), or the like, or may be implemented by a combination thereof. The photoelectric conversion system 1300 is connected to a vehicle information acquisition device 1320, and can acquire vehicle information such as a vehicle speed, a yaw rate, and a steering angle. The photoelectric conversion system 1300 is connected to a control electronic control unit (ECU) 1330 that is a control unit that outputs a control signal for causing a vehicle to generate braking force based on a determination result of the collision determination unit 1318. The photoelectric conversion system 1300 is also connected to an alert device 1340 that generates an alert to a driver based on the determination result of the collision determination unit 1318. For example, in a case where the possibility of collision is high as the determination result of the collision determination unit 1318, the control ECU 1330 performs vehicle control to avoid a collision and reduce damage by applying a brake, releasing an accelerator, suppressing engine output, or the like. The alert device 1340 issues an alert to a user by sounding an alarm or the like, displaying alert information on a screen of a car navigation system or the like, vibrating a seat belt or a steering wheel, or the like.

In the present exemplary embodiment, the photoelectric conversion system 1300 images surroundings of the vehicle, for example, a front side or a rear side of the vehicle. FIG. 13B illustrates the photoelectric conversion system in a case of imaging the front side (imaging range 1350) of the vehicle. The vehicle information acquisition device 1320 transmits an instruction to the photoelectric conversion system 1300 or the imaging device 1310. Such a configuration makes it possible to further improve accuracy of ranging.

Although the example of the control for avoiding a collision with another vehicle is described above, the present exemplary embodiment is applicable to self-driving control to follow another vehicle, self-driving control to not stray from a traffic lane, and the like. Further, the photoelectric conversion system can be applied to a moving body (moving apparatus) such as a vessel, an aircraft, and an industrial robot without being limited to a vehicle such as an automobile. In addition, the photoelectric conversion system can be applied widely to an apparatus that uses object recognition, such as an intelligent transport system (ITS) without being limited to the moving body.

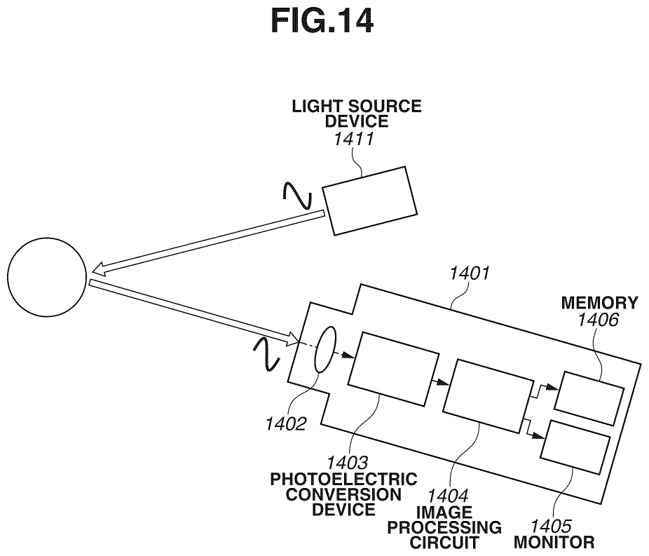

A photoelectric conversion system according to a tenth exemplary embodiment is described with reference to FIG. 14. FIG. 14 is a block diagram illustrating a configuration example of a distance image sensor that is the photoelectric conversion system according to the present exemplary embodiment.

As illustrated in FIG. 14, a distance image sensor 1401 includes an optical system 1402, a photoelectric conversion device 1403, an image processing circuit 1404, a monitor 1405, and a memory 1406. The distance image sensor 1401 can acquire a distance image corresponding to a distance to an object by receiving light (modulated light or pulsed light) that is emitted from a light source device 1411 to the object and is reflected on a surface of the object.

The optical system 1402 includes one or a plurality of lenses, guides image light (incident light) from the object to the photoelectric conversion device 1403, and causes the image light to form an image on a light reception surface (sensor unit) of the photoelectric conversion device 1403.

As the photoelectric conversion device 1403, the photoelectric conversion device according to any of the above-described exemplary embodiments is applied, and a distance signal that indicates the distance determined from a light reception signal output from the photoelectric conversion device 1403 is supplied to the image processing circuit 1404.

The image processing circuit 1404 performs image processing to construct a distance image based on the distance signal supplied from the photoelectric conversion device 1403. Further, the distance image (image data) acquired by the image processing is supplied to and displayed on the monitor 1405, or supplied to and stored (recorded) in the memory 1406.

By being applied with any of the above-described photoelectric conversion devices, the distance image sensor 1401 configured as above can acquire, for example, a more accurate distance image along with improvement in characteristics of the pixels.

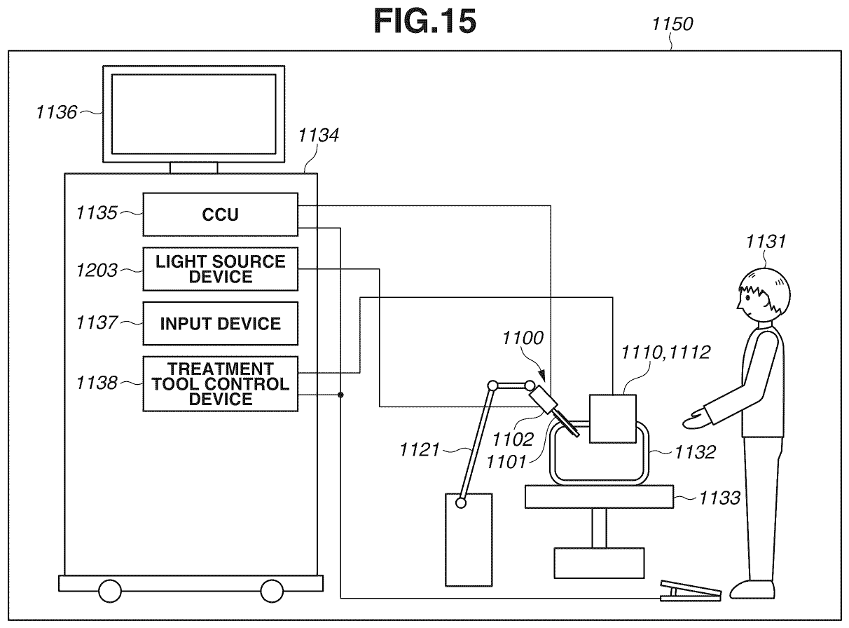

A photoelectric conversion system according to an eleventh exemplary embodiment is described with reference to FIG. 15. FIG. 15 is a diagram schematically illustrating an example of a configuration of an endoscope operation system that is the photoelectric conversion system according to the present exemplary embodiment.

FIG. 15 illustrates a state where an operator (doctor) 1131 performs an operation on a patient 1132 on a patient bed 1133 by using an endoscope operation system 1150. As illustrated, the endoscope operation system 1150 includes an endoscope 1100, an operation tool 1110, and a cart 1134 on which various kinds of devices for an endoscopic operation are mounted.

The endoscope 1100 includes a lens barrel 1101 a region thereof with a predetermined length from a distal end is inserted into a body cavity of the patient 1132, and a camera head 1102 connected to a proximal end of the lens barrel 1101. In the illustrated example, the endoscope 1100 configured as a rigid scope including the rigid lens barrel 1101 is illustrated; however, the endoscope 1100 may be configured as a flexible scope including a flexible lens barrel.

An opening portion into which an objective lens is fitted is arranged at a tip of the lens barrel 1101. A light source device 1203 is connected to the endoscope 1100. Light generated by the light source device 1203 is guided to the tip of the lens barrel 1101 by a light guide extending inside the lens barrel 1101, and is emitted toward an observation object in the body cavity of the patient 1132 through the objective lens. The endoscope 1100 may be a forward-viewing endoscope, an oblique-viewing endoscope, or a side-viewing endoscope.

An optical system and a photoelectric conversion device are arranged inside the camera head 1102, and reflected light (observation light) from the observation object is condensed to the photoelectric conversion device by the optical system. The observation light is photoelectrically converted by the photoelectric conversion device, and an electric signal corresponding to the observation light, i.e., an image signal corresponding to an observation image, is generated. As the photoelectric conversion device, the photoelectric conversion device according to any of the above-described exemplary embodiments is usable. The image signal is transmitted as RAW data to a camera control unit (CCU) 1135.

The CCU 1135 includes a central processing unit (CPU), a graphics processing unit (GPU), and the like, and totally controls operation of the endoscope 1100 and a display device 1136. Further, the CCU 1135 receives the image signal from the camera head 1102, and performs various kinds of image processing for displaying an image based on the image signal, such as development processing (demosaic processing), on the image signal.

The display device 1136 displays an image based on the image signal subjected to the image processing by the CCU 1135 under the control of the CCU 1135.

The light source device 1203 includes a light source, such as a light-emitting diode (LED), and supplies irradiation light for imaging an operative site and the like, to the endoscope 1100.

An input device 1137 is an input interface for the endoscope operation system 1150. A user can input various kinds of information and instructions to the endoscope operation system 1150 through the input device 1137.

A treatment tool control device 1138 controls driving of an energy treatment tool 1112 for cauterization and incision of tissue, sealing of blood vessels, and the like.

The light source device 1203 that supplies the irradiation light to image the operative site to the endoscope 1100 can include, for example, an LED, a laser light source, or a white light source including a combination thereof. In a case where the white light source includes a combination of red, green, and blue (RGB) laser light sources, since output intensities and output timings of respective colors (wavelengths) can be controlled with high accuracy, the light source device 1203 can adjust white balance of a captured image. Further, in this case, laser beams can be applied to the observation object from the RGB laser light sources in a time-division manner, and driving of imaging elements of the camera head 1102 can be controlled in synchronization with irradiation timings. This makes it possible to capture an image corresponding to each of RGB in a time-division manner. According to the method, a color image can be acquired without arranging color filters on the imaging elements.

Driving of the light source device 1203 may be controlled such that intensity of output light is changed at predetermined time intervals. Driving of the imaging elements of the camera head 1102 is controlled in synchronization with a timing of changing the light intensity to acquire images in a time-division manner, and the images are combined. This makes it possible to generate an image with a high dynamic range without underexposure and overexposure.

Further, the light source device 1203 may be configured to supply light of a predetermined wavelength band suitable for special light observation. In the special light observation, for example, wavelength dependency of absorption of light by tissue of the body is used. More specifically, by irradiating with light of a narrow band as compared with irradiation light (i.e., white light) in normal observation, predetermined tissue, such as blood vessels in a superficial layer of a mucous membrane, is imaged with high contrast.

Alternatively, in the special light observation, fluorescent observation in which an image is acquired with fluorescence generated by irradiation with excitation light may be performed. In the fluorescent observation, for example, tissue of the body is irradiated with excitation light, and fluorescence from the tissue is observed, or a reagent, such as indocyanine green (ICG), is locally injected into tissue of the body, and the tissue of the body is irradiated with excitation light corresponding to a fluorescence wavelength of the reagent to acquire a fluorescent image. The light source device 1203 can be configured to supply the narrowband light and/or the excitation light suitable for such special light observation.

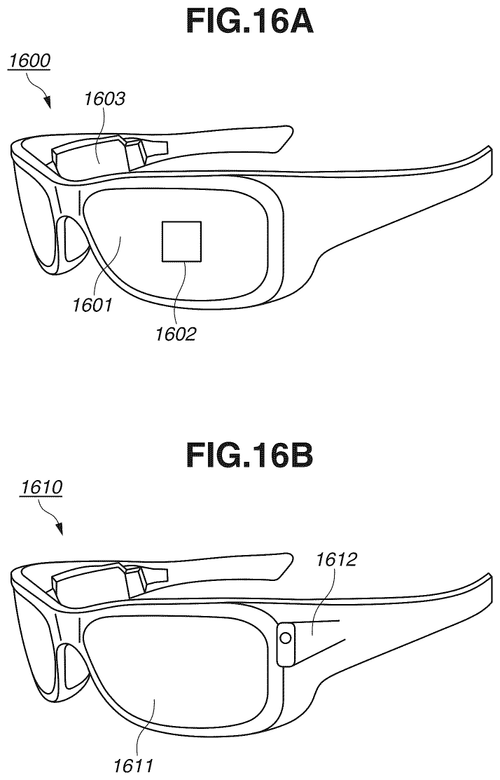

A photoelectric conversion system according to a twelfth exemplary embodiment is described with reference to FIGS. 16A and 16B. FIG. 16A illustrates eyeglasses 1600 (smart glasses) that is the photoelectric conversion system according to the present exemplary embodiment. The eyeglasses 1600 include a photoelectric conversion device 1602. The photoelectric conversion device 1602 is the photoelectric conversion device according to any of the above-described exemplary embodiments. A display device including a light emitting device, such as an organic light-emitting diode (OLED) and an LED, may be arranged on a rear surface side of a lens 1601. One or a plurality of photoelectric conversion devices 1602 may be arranged. A plurality of types of photoelectric conversion devices 1602 may be used in combination. An arrangement position of the photoelectric conversion device 1602 is not limited to a position illustrated in FIG. 16A.

The eyeglasses 1600 further include a control device 1603. The control device 1603 functions as a power supply that supplies power to the photoelectric conversion device 1602 and the above-described display device. The control device 1603 also controls operation of the photoelectric conversion device 1602 and the display device. The lens 1601 includes an optical system for condensing light to the photoelectric conversion device 1602.

FIG. 16B illustrates eyeglasses 1610 (smart glasses) according to one application example. The eyeglasses 1610 includes a control device 1612, and a photoelectric conversion device equivalent to the photoelectric conversion device 1602 and the display device are mounted on the control device 1612. In a lens 1611, an optical system for projecting light emitted from the photoelectric conversion device in the control device 1612 and from the display device is formed, and an image is projected to the lens 1611. The control device 1612 functions as a power supply that supplies power to the photoelectric conversion device and the display device, and controls operation of the photoelectric conversion device and the display device. The control device 1612 may include a line-of-sight detection unit that detects a line of sight of a wearer. The line of sight may be detected using infrared light. An infrared light emitting unit emits infrared light to an eyeball of a user viewing a displayed image. An imaging unit including a light reception element detects reflected light of the infrared light from the eyeball. As a result, a captured image of the eyeball is acquired. A reduction unit that reduces light from the infrared light emitting unit to a display unit in a planar view is provided to reduce deterioration of image quality.

The line of sight of the user to the displayed image is detected from the captured image of the eyeball acquired by imaging with the infrared light. A known method can be applied to line-of-sight detection using the captured image of the eyeball. As an example, a line-of-sight detection method based on Purkinje images caused by reflection of irradiation light on cornea can be used.

More specifically, line-of-sight detection processing based on a pupil-corneal reflection method is performed. The line of sight of the user is detected by calculating, by using the pupil-corneal reflection method, a line-of-sight vector indicating a direction (rotation angle) of the eyeball based on an image of a pupil included in the captured image of the eyeball and the Purkinje images.

The display device according to the present exemplary embodiment may include the photoelectric conversion device including a light reception element, and control the displayed image of the display device based on line-of-sight information on the user from the photoelectric conversion device.

More specifically, based on the line-of-sight information, a first field-of-view region viewed by the user and a second field-of-view region other than the first field-of-view region are determined in the display device. The first field-of-view region and the second field-of-view region may be determined by a control device of the display device, or may be determined by an external control device and received. In a display region of the display device, display resolution of the first field-of-view region may be controlled to be higher than display resolution of the second field-of-view region. In other words, the display resolution of the second field-of-view region may be lowered than the display resolution of the first field-of-view region.

The display region may include a first display region and a second display region different from the first display region, and a region having high priority may be determined from the first display region and the second display region based on the line-of-sight information. The first display region and the second display region may be determined by the control device of the display device, or may be determined by an external control device and received. Resolution of the region having high priority may be controlled to be higher than resolution of the region other than the region having high priority. In other words, the resolution of the region having relatively low priority may be lowered.

The first field-of-view region and the region having high priority may be determined using artificial intelligence (AI). The AI may be a model configured to estimate a line-of-sight angle and a distance to a target object in the line of sight from an image of an eyeball by using, as training data, the image of the eyeball and the direction actually viewed by the eyeball in the image. An AI program may be held by the display device, the photoelectric conversion device, or the external device. In a case where the external device holds the AI program, the AI program is transmitted to the display device through communication.

In a case where display control is performed based on line-of-sight detection, the exemplary embodiment can be suitably applied to the smart glasses further including the photoelectric conversion device that images outside. The smart glasses can display captured external information in real time.

The present disclosure is not limited to the above-described exemplary embodiments, and can be variously modified. For example, an example in which a part of the configuration of any of the exemplary embodiments is added to the configuration of another exemplary embodiment, and an example in which a part of the configuration of any of the exemplary embodiments is replaced with a part of the configuration of another exemplary embodiment are also included in the exemplary embodiments of the present disclosure.

The photoelectric conversion systems according to the eighth and ninth exemplary embodiments are examples of the photoelectric conversion system to which the photoelectric conversion device can be applied, and the photoelectric conversion system to which the photoelectric conversion device according to any of the exemplary embodiments of the present disclosure is applicable is not limited to the configurations illustrated in FIG. 12 and FIGS. 13A and 13B. This is true of the time of flight (ToF) system according to the tenth exemplary embodiment, the endoscope according to the eleventh exemplary embodiment, and the smart glasses according to the twelfth exemplary embodiment.

The above-described exemplary embodiments are merely specific examples for implementing the present disclosure, and should not be construed as limiting the technical scope of the present disclosure. In other words, the present disclosure can be implemented in various forms without departing from the technical idea or main features of the present disclosure.

According to the exemplary embodiments, it is possible to provide the photoelectric conversion device further improved in noise characteristics.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-083369, filed May 19, 2023, which is hereby incorporated by reference herein in its entirety.

What is claimed is:

1. A conversion device comprising a first component including a first substrate, a conversion unit, a diffusion portion, and a transfer gate, the first substrate including a first surface and a second surface opposed to the first surface, the conversion unit being arranged in the first substrate, the transfer gate being arranged on a first surface side of the first substrate and being configured to transfer a signal charge generated in the conversion unit to the diffusion portion,
wherein the first component further includes a first embedded electrode connected to the conversion unit, and a second embedded electrode connected to the diffusion portion, and
wherein a depth from the first surface to an end portion of the first embedded electrode on a second surface side and a depth from the first surface to an end portion of the second embedded electrode on the second surface side are different from each other.

2. The conversion device according to claim 1, further comprising a second component including a second substrate, and the second component being stacked on the first component.

3. The conversion device according to claim 2,
wherein the second substrate includes a third surface and a fourth surface opposed to the third surface,
wherein the first component and the second component are stacked so that the second surface and the third surface face each other,
wherein the second substrate includes a through electrode penetrating from the third surface to the fourth surface, and
wherein a gate of a transistor is formed on the fourth surface.

4. The conversion device according to claim 3, wherein the first embedded electrode is an electrode connecting the diffusion portion and the gate of the transistor and transferring a signal based on the charge generated in the conversion unit.

5. The conversion device according to claim 1, wherein the second embedded electrode is an electrode applying a voltage to the conversion unit.

6. The conversion device according to claim 1, wherein the depth from the first surface to the end portion of the first embedded electrode on the second surface side is greater than the depth from the first surface to the end portion of the second embedded electrode on the second surface side.

7. The conversion device according to claim 6,
wherein a first region of a first conductive type is formed around the first embedded electrode,
wherein a second region of a second conductive type is formed around the second embedded electrode, and
wherein, in comparison of a depth from the first surface, an end portion of the first region on the second surface side is close to the second surface compared with an end portion of the second region on the second surface side.

8. The conversion device according to claim 1, wherein the depth from the first surface to the end portion of the second embedded electrode on the second surface side is greater than the depth from the first surface to the end portion of the first embedded electrode on the second surface side.

9. The conversion device according to claim 8,
wherein a first region of a first conductive type is formed around the first embedded electrode,
wherein a second region of a second conductive type is formed around the second embedded electrode, and
wherein, in comparison of a depth from the first surface, an end portion of the second region on the second surface side is close to the second surface compared with an end portion of the first region on the second surface side.

10. The conversion device according to claim 1, wherein the transfer gate is a vertical transfer gate.

11. The conversion device according to claim 3, further comprising a plurality of first embedded electrodes,
wherein the through electrode is connected to the plurality of first embedded electrodes.

12. The conversion device according to claim 1, further comprising a plurality of conversion units,
wherein the plurality of conversion units includes a conversion unit in which the depth from the first surface to the end portion of the first embedded electrode on the second surface side and the depth from the first surface to the end portion of the second embedded electrode on the second surface side are different from each other, and a conversion unit in which the depth from the first surface to the end portion of the first embedded electrode on the second surface side and the depth from the first surface to the end portion of the second embedded electrode on the second surface side are equal to each other.

13. A conversion system comprising:
the conversion device according to claim 1; and
a signal processing unit configured to generate an image by using a signal output from the conversion device.

14. The conversion system according to claim 13, wherein the conversion device further comprises a second component including a second substrate, and the second component being stacked on the first component.

15. The conversion system according to claim 13, wherein, in the conversion device, the depth from the first surface to the end portion of the first embedded electrode on the second surface side is greater than the depth from the first surface to the end portion of the second embedded electrode on the second surface side.

16. The conversion system according to claim 13, wherein, in the conversion device, the depth from the first surface to the end portion of the second embedded electrode on the second surface side is greater than the depth from the first surface to the end portion of the first embedded electrode on the second surface side.

17. A moving body comprising:
the conversion device according to claim 1; and
a control unit configured to control movement of the moving body by using a signal output from the conversion device.

18. The moving body according to claim 17, wherein the conversion device further comprises a second component including a second substrate, and the second component being stacked on the first component.

19. The moving body according to claim 17, wherein, in the conversion device, the depth from the first surface to the end portion of the first embedded electrode on the second surface side is greater than the depth from the first surface to the end portion of the second embedded electrode on the second surface side.

20. The moving body according to claim 17, wherein, in the conversion device, the depth from the first surface to the end portion of the second embedded electrode on the second surface side is greater than the depth from the first surface to the end portion of the first embedded electrode on the second surface side.
